(19) United States
(12) Patent Application Publication
(10) Pub. No.: US 2004/0032667 A1
(43) Pub. Date: Feb. 19, 2004

(54) Technique for microstructuring replication mold

(76) Inventors: Michael Gale, Wettswil (CH); Juergen Sochtig, Opfikon (CH); Markus Rossi, Tous (CH)

Correspondence Address: FISH & RICHARDSON, PC, 12390 EL CAMINO REAL, SAN DIEGO, CA, 92130-2081, US

(21) Appl. No.: 10/257,005

(22) PCT Filed: Apr. 2, 2001
(86) PCT No.: PCT/GB01/01485

(30) Foreign Application Priority Data
Apr. 3, 2000 (GB) 0008024.2

(51) Int. Cl. G02B 3/00; G02B 7/00; G02B 9/00; G02B 11/00; G02B 13/00; G02B 15/00; G02B 17/00; G02B 25/00; B29C 33/00; G03F 7/18; G03F 7/24; G03F 7/40; G03H 1/04; G03H 1/26; G02B 1/12; B29D 11/00; C25D 5/02

(52) U.S. Cl. 359/642; 359/647; 249/187.1; 430/321; 430/323; 430/324; 430/1; 359/23; 264/1.27; 264/2.5; 205/122

(57) ABSTRACT

A surface microstructure is superimposed on the surface of a replication mould such as an injection moulding tool insert by laser interference exposure of a mask pattern and etching or electroplating the additional microstructure. The technique enables the post-processing of planar and non-planar replication moulds with additional microstructure to improve the functionality and value of the moulded components. A major area of application is an anti-reflection surface for injection moulded polymer optical components, achieved by the superposition of submicrometer anti-reflection grating structure onto injection moulding tool inserts.

### FIELD OF THE INVENTION

This invention relates to the production of moulded polymer components, for example, by injection moulding, hot embossing, UV-embossing or other replication technologies. Examples of such components include optical elements such as lenses and optical microsystems composed of multiple elements. Applications are primarily in optical systems for sensors, instruments, telecommunications and displays.

### PRIOR ART

Replication technology such as injection moulding is an important fabrication technology for optical elements and Microsystems. A summary of replication technology for optical elements can be found in (1). The technology for fabrication of moulds directly or from an original form is well established. Major approaches are the direct fabrication of the mould insert in metal by high precision machining or diamond turning, and the electroforming of a Ni shim or mould insert from an original form.

The use of very fine surface structures with micrometer or submicrometer feature size is also well known (2). Typical structures for imparting anti-reflection behaviour on optical surfaces are subwavelength grating structures with linewidths and depths of about 150 nm for the visible wavelength region. Similar microstructures can be used to achieve other properties such as polarising behaviour.

Conventional techniques such as direct machining are not capable of producing very fine micro- or nano-structures such as required for antireflection grating surfaces. The fabrication of an original form with such grating microstructure is possible, but complicates the basic form fabrication process. Examples of prior art can be found in:

Ref. (3) U.S. Pat. No. 6,021,106

Describes the fabrication of a moulding surface in quartz substrate by etching a multi-level diffraction pattern. This approach is limited to microstructures in the order of micrometers in relief amplitude and is not suitable for fabricating deeper refractive lenses with relief amplitudes in the order of mm. It is also limited to relatively shallow (micrometer relief) microstructures together with materials such as quartz which can be patterned lithographically and is not suitable for the preferred metal tool inserts.

Ref. (4) U.S. Pat. No. 5,958,469

Describes the fabrication of a moulding tool using single-point-diamond turning. The approach described is limited to circularly symmetric microstructures and is not suitable for fabricating submicrometer squarewave grating profiles.

In general terms, the invention may therefore solve the problems of the prior art described above by allowing the separation of the basic mould form, for example a curved surface for a moulded lens element, from the superposition of a very fine microstructure.

### SUMMARY OF THE INVENTION

The invention provides a method for fabricating a mould as defined in the appended independent claim, to which reference should now be made. Preferred or advantageous features of the invention are set out in dependent subclaims.

The present invention may thus advantageously allow the superposition of microstructure such as a high resolution, submicrometer linewidth grating onto the surface of a replication mould. The mould insert is typically metal and is fabricated by conventional techniques such as high precision machining, diamond turning or electroforming.

The new technique preferably comprises the following processing steps:

1. Mask fabrication by laser interference (holographic) exposure of a thin resist film on the mould surface to be modified.

2. Fabrication of the microstructure by either

a) etching the mould surface to a predetermined depth or

b) electroplating additional metal to a predetermined thickness

3. Removal of the mask material

The novelty lies in the direct processing of the mould insert itself combined with the use of laser interference exposure or, preferably, holographic exposure to generate a submicrometer grating exposure pattern with a large depth of focus suitable for exposing non-planar mould surfaces such as lens profiles. This overcomes the limitations of the prior art in which high resolution grating structure on curved mould surfaces cannot readily be fabricated.

### DESCRIPTION OF SPECIFIC EMBODIMENTS AND BEST MODE

Embodiments of the invention will now be described by way of example, with reference to the drawings, in which:

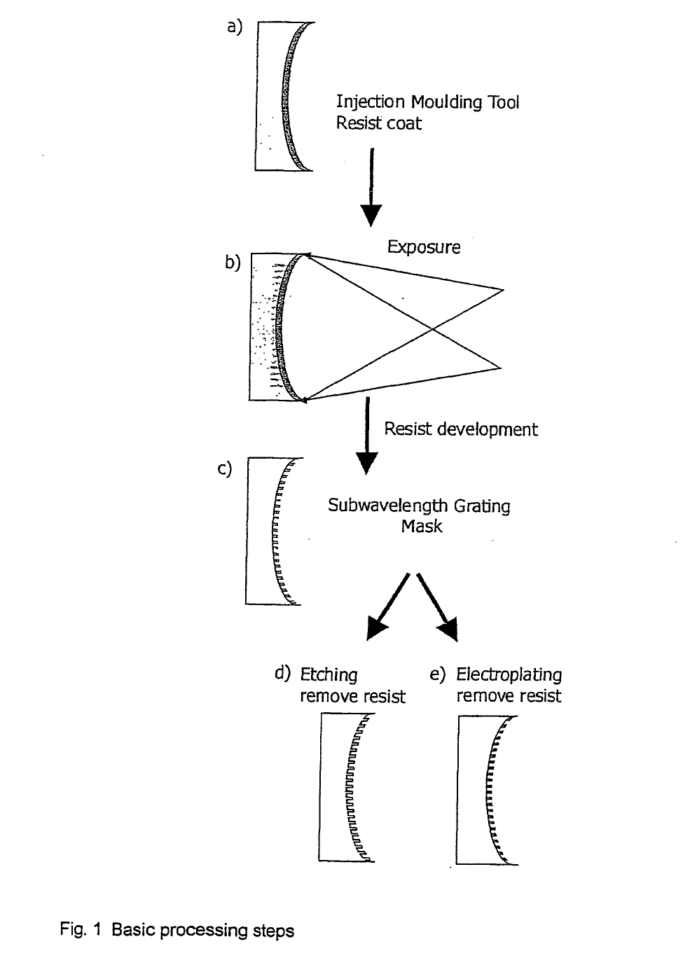

FIG. 1 illustrates the processing steps of a method embodying the invention; and

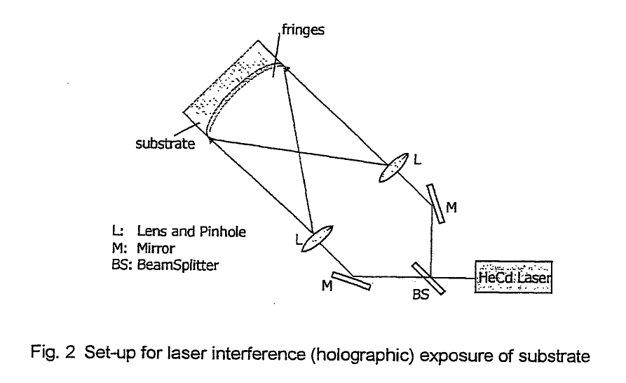

FIG. 2 illustrates the holographic exposure of a substrate of a curved mould surface.

FIG. 1 illustrates the technique for the fabrication of a high resolution, subwavelength AR (Anti-reflection) grating microstructure. Such gratings have the following typical parameters:

Periodicity: 200-400 nm

Linewidths: 100-200 nm

Relief depth: 100-200 nm

The details of the processing steps (c.f. FIG. 1) are as follows:

1. Mask Fabrication

(a) The mould insert is coated with a thin film of photoresist (such as Shipley 1800 series). The coating of uniform thickness films on non-planar surfaces is difficult and requires special coating technology. An alternative to commercial photoresists are developmental systems such as dry resists of the chalcogenide family (5), which have advantages for curved and other non-planar mould forms. Such resists can be deposited by evaporation technology, and are thus relatively easy to apply in uniform film thickness on non-planar surfaces.

(b) Exposure of the photoresist layer in a 2-beam laser interference set-up. As illustrated in FIG. 1, the interference of the 2 laser beams results in a fringe pattern perpendicular to the mould and with large depth of focus of typically >100 mm and in practice limited by the volume in which the beams overlap. This is ideal for exposing curved and other non-planar surfaces. The fringe pattern is slightly chirped (periodicity varying with the distance from the center of the pattern), but this is of no consequence for this application. (Non-chirped grating patterns can be realised by using additional lenses to collimate the beams.)

As a laser for high resolution pattern, a HeCd laser emitting in the UV (wavelength λ=326 nm) or the blue (λ=442 nm) is suitable; an angle of 60° between the interfering beams, for example, results in a fringe periodicity of Λ˜510 nm for the wavelength λ=442 nm.

FIG. 2 shows a typical exposure set-up as used in a state-of-the-art laser interference (holographic) exposure system. The beam from the laser is split into two and each of these is expanded by a lens/pinhole spatial filter combination to form a divergent wavefront. The path lengths of the 2 beams must be kept as equal as possible, typically to within a few mm. The photoresist coated substrate is positioned within the volume in which the beams overlap and form an interference fringe pattern. Non planar substrates such as concave and convex lens shapes, or more complex optical forms, can conveniently be exposed by a submicrometer fringe pattern in this way.

Techniques developed for fabricating squarewave grating mask profile can also be used to advantage here—see for example Ref. (6).

(c) After exposure, the phototesist is developed with the appropriate developer down to the mould surface to form the required mask pattern.

2. Grating Structure Fabrication

The grating microstructure required has a typical amplitude of about 100-200 nm for antireflection structures; The amplitude can be significantly higher, in the order of micrometers, for other applications. It can be fabricated by either etching the substrate or electroplating a thin film between the grating mask.

(d) Etching

The substrate is etched to the required depth. For etching high resolution microstructure, dry etching approaches are preferred. Typical substrate materials or mould insets are nickel or steel. The shallow grating depths required (˜150 nm) can be etched by Ar ion etching or by Reactive Ion Etching (see, for example, information in http:/fwww.oxfordplasma.de). For very shallow microstructures (typically <100 nm relief), it is also possible to use wet etching techniques.

(e) Electroplating

A thin layer of metal is deposited on the substrate by electroplating. The resist mask prevents deposition in the areas masked, so that a high resolution grating microstructure is formed on the substrate surface. An example of a nickel electroplating procedure which can be used is given in Ref. (7). Other metals and procedures known in the art can also be used.

3. Resist Mask Removal

Following the etching or electroplating, the resist mask is stripped to leave the microstructured surface. The tool insert is cleaned and ready for use in the injection moulding machine.

The present invention is highly suited to fabricating very fine gratings such as the anti-reflection microstructure described above. It is not, however, limited to this. By suitable choice of the interfering beam geometries and spatial positions, other interference patterns such as diffractive elements and microrelief features can be generated and superimposed on the mould surface.

Documents Incorporated Herein by Reference:

(1). M. T. Gale, Replication, Ch. 6 in Micro-Optics: Elements, systems and applications, H. P. Herzig, Ed., Taylor and Francis, London, 1997, ISBN 0 7484 0481 3 HB.

(2) Heine, R. H. Morf and M. T. Gale, “Coated submicron gratings for broadband antireflection in solar energy applications”, J. Modem Optics, 43, pp.1371-1377 (1996).

(3) U.S. Pat. No. 6,021,106, Welch et al., “Molding diffractive optical elements”, Feb. 1, 2000.

(4) U.S. Pat. No. 5,958,469, Richards, “Method for fabricating tools for molding diffractive surfaces on optical lenses”, Sep. 28, 1999.

(5) A. Stronski, M. Vleck, P. E. Shepeljavi, A. Skienar and S. A. Kostyukevich, “Photosensitive properties of Ad40S20Se40 thin layers in application for gratings fabrication”, Proc. EOS Topical Meeting on “Diffractive Optics”, Jena, D, Aug. 23-25, 1999, ISSN 1167-5357, pp187-188.

(6) R. E. Kunz et al., “Grating couplers in tapered waveguides for integrated optical sensing”, Proc. SPIE 2068, pp. 313-325, 1994

(7) M. T. Gale and K. Knop, “Surface-relief Images for Color Reproduction”, Focal Press, London, 1980, ISBN 0 240 51068 2, pp.105-108.

1. A method for fabricating a mould, comprising the steps of;
depositing a resist on a surface of the mould;
patterning the resist in a predetermined pattern;
modifying the shape of the mould surface according to the pattern defined by the exposed resist; and
removing the resist.

2. A method according to claim 1, in which the step of modifying the shape of the mould surface comprises the step of etching the mould surface.

3. A method according to claim 1, in which the step of modifying the shape of the mould surface comprises the step of plating the mould surface.

4. A method according to claim 1, 2 or 3, in which the step of patterning the resist comprises exposing the resist to a laser interference pattern or a holographic image.

5. A method according to any preceding claim, in which the mould surface is curved.

6. A method according to any preceding claim, in which the modification to the shape of the mould surface has a characteristic dimension of between 100 nm and 400 nm.

7. A method according to any preceding claim, in which the modification to the shape of mould is for forming an antireflection surface, diffractive elements or microrelief features in th surface of an article made in the mould.

8. A mould fabricated using a method as defined in any preceding claim.

9. An article made using a mould as defined in claim 8.

10. An article according to claim 9, being an optical component, such as a lens or a lens for eyesight correction.
